(19) United States
(12) Patent Application Publication
(10) Pub. No.: US 2024/0004292 A1
(43) Pub. Date: Jan. 4, 2024

(54) POSITIVE PHOTORESIST RESIN COMPOSITION AND INSULATING FILM AND DISPLAY DEVICE BASED THEREON

(71) Applicant: DONGJIN SEMICHEM CO., LTD., Incheon (KR)

(72) Inventors: Tai Hoon YEO, Hwaseong-si (KR); Hyoc Min YOUN, Hwaseong-si (KR); Dong Myung KIM, Hwaseong-si (KR); Sun Hee LEE, Hwaseong-si (KR); Ah Rum PARK, Hwaseong-si (KR); Gun Seok JANG, Hwaseong-si (KR); Seok Hyun LEE, Hwaseong-si (KR); Nu Ri OH, Hwaseong-si (KR); In Ho SONG, Hwaseong-si (KR)

(21) Appl. No.: 18/467,941

(22) Filed: Sep. 15, 2023

Related U.S. Application Data
(63) Continuation of application No. PCT/KR2022/003725, filed on Mar. 17, 2022.

(30) Foreign Application Priority Data
Mar. 17, 2021 (KR) 10-2021-0034811

(51) Int. Cl. G03F 7/039; C08G 73/10; C08F 220/42; C08L 79/08; C08L 35/04

(52) U.S. Cl. CPC G03F 7/039; C08G 73/1046; C08F 220/42; C08L 79/08; C08L 35/04

(57) ABSTRACT

A positive-type photosensitive resin composition, an insulating film made from the same, and a display device including such insulating film are provided. The positive photosensitive resin composition is excellent in sensitivity and has excellent chemical resistance, heat resistance, and hygroscopicity by including a polymer containing a hydroxyl group.

### CROSS-REFERENCE TO RELATED APPLICATIONS

The present application is a Continuation of International Application No. PCT/KR2022/003725 filed Mar. 17, 2022, which claims priority from Korean Application No. 10-2021-0034811 filed Mar. 17, 2021. The aforementioned applications are incorporated herein by reference in their entireties.

### TECHNICAL FIELD

The present disclosure relates to a positive-type photosensitive resin composition with excellent sensitivity, an insulating film based thereon, and a display device comprising such insulating film.

### RELATED ART

Recently in the market, organic light emitting diodes (OLEDs), especially active matrix OLEDs (AMOLEDs), have been in the spotlight for various reasons among display devices.

Typically, an OLED device includes an organic insulating film, and a polyimide photosensitive resin composition is generally used in the formation of the organic insulating film. Techniques of substituting the polyamic esters with alkyls have been applied to polyamic esters among the polyimide precursors used in conventional polyimide photosensitive resin compositions, but polyamic esters substituted with alkyls are difficult to control solubility and have low sensitivity so that improvement measures therefor are urgently required.

### SUMMARY

An object of the present disclosure is to provide a positive-type photosensitive resin composition excellent in sensitivity, film thickness retention rate, adhesive force, chemical resistance, hygroscopicity, and heat resistance.

Another object of the present disclosure is to provide an insulating film including a cured body of the positive-type photosensitive resin composition.

Another object of the present disclosure is to provide a display device including the insulating film such that it has excellent driving reliability.

One embodiment of the present disclosure for achieving the above-described object provides a positive-type photosensitive resin composition including: a first polymer comprising one or more structures selected from the group consisting of polyamic acid ester, polyamic acid, and polyimide; a second polymer containing at least one hydroxyl group among repeating units; a photosensitizer; and a solvent, wherein the hydroxyl group (OH group) equivalent ratio of the first polymer to the second polymer is 1:0.04 to 1:74.

Specifically, the second polymer may contain one or more repeating units of Chemical Formula 1 or 2 below.

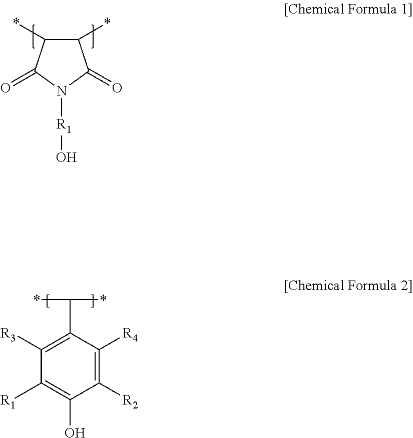

In Chemical Formula 1, R₁ is an organic group having 1 to 20 carbon atoms,

In Chemical Formula 2, R₁ to R₄ are each independently hydrogen, an organic group having 1 to 30 carbon atoms, or a substituent of Chemical Formula 3 below.

[symbol]

(CH₂)ₘ—O—R₅) [Chemical Formula 3]

In Chemical Formula 3, R₅ is an alkyl group having 1 to 3 carbon atoms, and m is an integer of 1 or 2.

According to another aspect of the present disclosure, an insulating film includes a cured body of the positive-type photosensitive resin composition.

According to another aspect of the present disclosure, a display device includes the insulating film.

The positive-type photosensitive resin composition according to embodiments of the present disclosure is excellent in sensitivity, film thickness retention rate, adhesive force, chemical resistance, and heat resistance. The pattern film including the positive-type photosensitive resin composition has an insignificant thickness change rate in a wet environment, and the display device including the positive-type photosensitive resin composition has an effect that the time (T₉₇) for the luminance to drop by 3% in the driving state is 1,000 hours or more. In addition, the positive-type photosensitive resin composition has an effect capable of improving productivity due to excellent sensitivity.

### BRIEF DESCRIPTION OF THE DRAWINGS

FIG. 1 schematically shows that a pattern film is formed on an indium tin oxide (ITO) substrate on which a pattern according to an embodiment of the present disclosure is formed, and electroluminescent lighting (EL) and aluminum are deposited thereon.

### DETAILED DESCRIPTION

The terms or words used in this specification and claims should not be construed as being limited to ordinary or dictionary meanings, and they should be interpreted as meanings and concepts consistent with the technical ideas of the present disclosure based on the principle that the inventor can appropriately define the concepts of the terms in order to explain his or her invention in the best way.

Therefore, since the configurations shown in Examples and Preparation Examples described in this specification are only one of the most preferred embodiments of the present disclosure, and do not represent all of the technical ideas of the present disclosure, it should be understood that there may be various equivalents and modifications that can be substituted for them at the time of this application.

Hereinafter, the Examples of the present disclosure will be described in detail so that those skilled in the art to which the present disclosure pertains can easily implement the present disclosure. However, the present disclosure can be implemented in many different forms and is not limited to the Preparation Examples and Examples described herein.

In this specification, “*” means a part that is to be connected to the same or different atom or chemical formula.

The positive-type photosensitive resin composition according to one embodiment of the present disclosure includes: a first polymer comprising one or more structures selected from the group consisting of polyamic acid ester, polyamic acid, and polyimide; a second polymer containing at least one hydroxyl group among repeating units; a photosensitizer; and a solvent, wherein the hydroxyl group (OH group) equivalent ratio of the first polymer to the second polymer is 1:0.04 to 1:74. As described above, when the hydroxyl group equivalent content of the first polymer to the hydroxyl group equivalent content of the second polymer (first polymer:second polymer) is 1:0.04 to 1:74, it may be possible to implement a cured film exhibiting remarkably improved sensitivity characteristics and having excellent hygroscopicity, adhesive force, heat resistance, film remaining rate, and chemical resistance at the same time compared to conventional usual polyimide-based photosensitive resin compositions. However, when the hydroxyl equivalent ratio of the first polymer and the second polymer is less than the above-described range, there may be a problem in that the sensitivity improvement effect is lowered, and when it is greater than the above-described ratio, there may be a problem in that the heat resistance and hygroscopicity of the cured film and the reliability and the like of the device decrease.

The positive-type photosensitive resin composition exhibits characteristics that excellent sensitivity, film thickness retention ratio, adhesive force, chemical resistance, and heat resistance are all excellent, and hygroscopicity is low.

According to another embodiment of the present disclosure, the second polymer may include one or more repeating units of Chemical Formula 1 or 2 below.

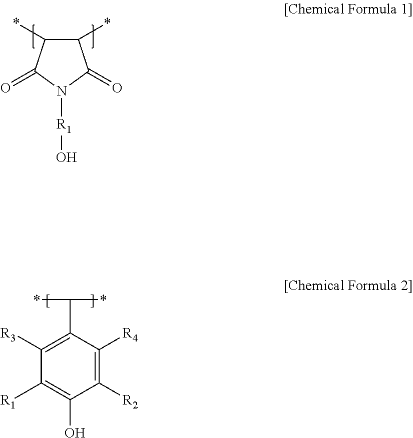

In Chemical Formula 1, R₁ is an organic group having 1 to 20 carbon atoms,

In Chemical Formula 2, R₁ to R₄ are each independently hydrogen, an organic group having 1 to 30 carbon atoms, or a substituent of Chemical Formula 3 below.

[symbol]

(CH₂)ₘ—O—R₅) [Chemical Formula 3]

In Chemical Formula 3, R₅ is an alkyl group having 1 to 3 carbon atoms, and
m is an integer of 1 or 2.

When a polymer containing a hydroxyl group in a repeating unit as shown in Chemical Formula 2 or 3 is used as the second polymer, a sensitivity improvement effect may be particularly exhibited.

According to one embodiment of the present disclosure, at least one of R₁ to R₄ in Chemical Formula 2 above may include a substituent of Chemical Formula 3 above. When at least one substituent of Chemical Formula 3 is included in the repeating unit of Chemical Formula 2, the adhesive force and chemical resistance of the cured film may be improved compared to the case where there is no substituent of Chemical Formula 3.

According to one embodiment of the present disclosure, the second polymer may include the repeating unit represented by Chemical Formula 1 above and may not include the repeating unit represented by Chemical Formula 2 above. When it includes the repeating unit represented by Chemical Formula 1 above and does not include the repeating unit represented by Chemical Formula 2 above, heat resistance of the photosensitive resin composition may have more excellent properties.

According to another embodiment of the present disclosure, the second polymer may specifically include only one repeating unit represented by Chemical Formula 1.

According to another embodiment of the present disclosure, the second polymer may include two or more types of repeating units represented by Chemical Formula 1 in which R₁ of Chemical Formula 1 has different structures. More specifically, the second polymer may include one or more of a repeating unit in which R₁ in Chemical Formula 1 above includes an aromatic ring structure and a repeating unit in which R₁ does not include the aromatic ring structure. The second polymer may include only a repeating unit in which R₁ includes an aromatic ring structure, or may include only a repeating unit in which R₁ does not include an aromatic ring structure, or may be included together.

In Chemical Formula 1 above, the repeating unit in which R₁ includes an aromatic ring structure may be represented by, for example, Chemical Formula 4 below, and the repeating unit in which R₁ does not include an aromatic ring structure may be represented by, for example, Chemical Formula 5 below.

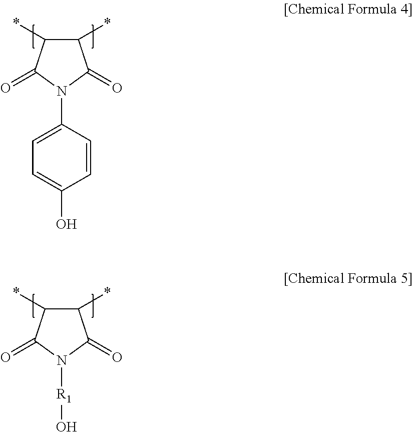

In Chemical Formula 5, R₁ is an aliphatic organic group having 1 to 20 carbon atoms.

In the second polymer, the repeating unit represented by Chemical Formula 4 and the repeating unit represented by Chemical Formula 5 may be used without limitation in the mixing ratio, and only the repeating unit represented by Chemical Formula 4 may be included, or only the repeating unit represented by Chemical Formula 5 may be included. In the second polymer, a higher molar ratio of the repeating unit represented by Chemical Formula 5 than that of the repeating unit represented by Chemical Formula 4 may be more advantageous in terms of permeability, but the film thickness retention rate may be relatively lowered so that it may be appropriately adjusted according to more necessary characteristics. For example, the repeating unit represented by Chemical Formula 4 above may be included at a ratio of 1 to 80 mol %, specifically 10 to 50 mol %, and more specifically 10 to 30 mol %, but is not limited thereto. It can be used by adjusting the molar ratio to an appropriate level.

According to another embodiment of the present disclosure, more specifically, the second polymer may further include repeating units represented by Chemical Formulas 6 to 7 below in addition to the repeating unit represented by Chemical Formula 1 or the repeating unit represented by Chemical Formula 2. The second polymer may be composed of only the repeating unit represented by Chemical Formula 4 above, and in this case, the sensitivity improvement effect of the photosensitive resin composition may be excellent even if other repeating units are not included. However, when the second polymer includes the repeating unit represented by Chemical Formula 5 above, the film thickness retention rate may be more effectively improved when one or more repeating units among the repeating units represented by Chemical Formulas 6 to 7 above are included together.

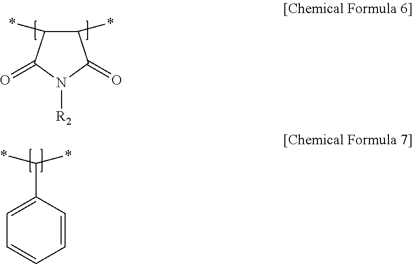

In Chemical Formula 6, R₂ may be an aryl group or an alkyl group, and in the case of an aryl group, it may be more effective against trade-offs that occur when sensitivity of the photosensitive resin composition is improved, that is, a decrease in film thickness retention rate, adhesive force, or the like. Specifically, in Chemical Formula 6 above, R₂ may be a substituted or unsubstituted aryl group having 6 to 30 carbon atoms or an alkyl group having 1 to 10 carbon atoms.

When the second polymer includes the repeating units represented by Chemical Formulas 6 to 7 above, it is preferable that the sum of the repeating units represented by Chemical Formulas 6 to 7 above is 30 mol % or less with respect to the total repeating units of the second polymer. When the sum of the repeating units represented by Chemical Formulas 6 to 7 above is contained in the second polymer in an amount of more than 30 mol %, there may be a problem in that the sensitivity improvement effect of the photosensitive resin composition deteriorates.

The first and second polymers may each independently have a weight average molecular weight (Mw) of 1,000 to 50,000 g/mol. When the first and second polymers have a weight average molecular weight of less than 1,000 g/mol, problems such as film thickness retention rate and adhesive force defects, deterioration in heat resistance, and the like may occur, and when they have a weight average molecular weight exceeding 50,000 g/mol, there may be problems in that sensitivity is not improved and residues generate in the pattern formation part.

The first polymer may specifically include a repeating unit represented by Chemical Formula 8 below and a repeating unit represented by Chemical Formula 9 below.

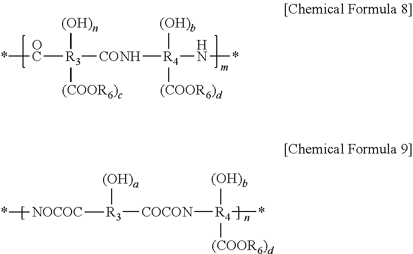

In Chemical Formulas 8 and 9, R₃ is a divalent to octavalent organic group having two or more carbon atoms, R₄ is a divalent to octavalent organic group having two or more carbon atoms, R₅ and R₆ are each independently a hydrogen atom or an organic group having 1 to 20 carbon atoms, a and b are each independently 0 to 4, c and d are each independently 0 to 2, and a+b is 1 or more. When a, b, c, or d is 0, the corresponding substituent is a hydrogen atom, m and n represent molar ratios of 0 to 100 of the repeating unit represented by Chemical Formula 8 and the repeating unit represented by Chemical Formula 9, respectively, and m+n=100.

The first polymer and the second polymer may have a weight ratio of 50:50 to 95:5. When the first polymer and the second polymer are contained at a weight ratio of 50:50 to 95:5, all of the sensitivity, film thickness retention ratio, adhesive force, chemical resistance, and heat resistance may be exhibited particularly excellently.

It is preferable that the positive-type photosensitive resin composition includes 5 to 50 parts by weight of the photosensitizer based on 100 parts by weight of the total of the first polymer and the second polymer. When the photosensitizer is included in an amount of less than 5 parts by weight, the photosensitivity of the photosensitive resin composition may deteriorate to cause a problem in that the sensitivity on the substrate decreases, and when the photosensitizer is included in an amount of more than 50 parts by weight, sensitivity may decrease, and a problem of generating residue on the pattern part may occur.

The photosensitizer may be, for example, a quinonediazide compound. When the photosensitizer is a quinonediazide compound, the photosensitivity of the resin composition including the first polymer and the second polymer may be excellent, but is not limited to the above example.

When the positive-type photosensitive resin composition further includes a phenolic hydroxyl group-containing crosslinkable compound, there is an effect of further improving chemical resistance.

The phenolic hydroxyl group-containing crosslinkable compound may include, for example, one or more selected from the group consisting of compounds represented by Chemical Formulas 10 to 27 below.

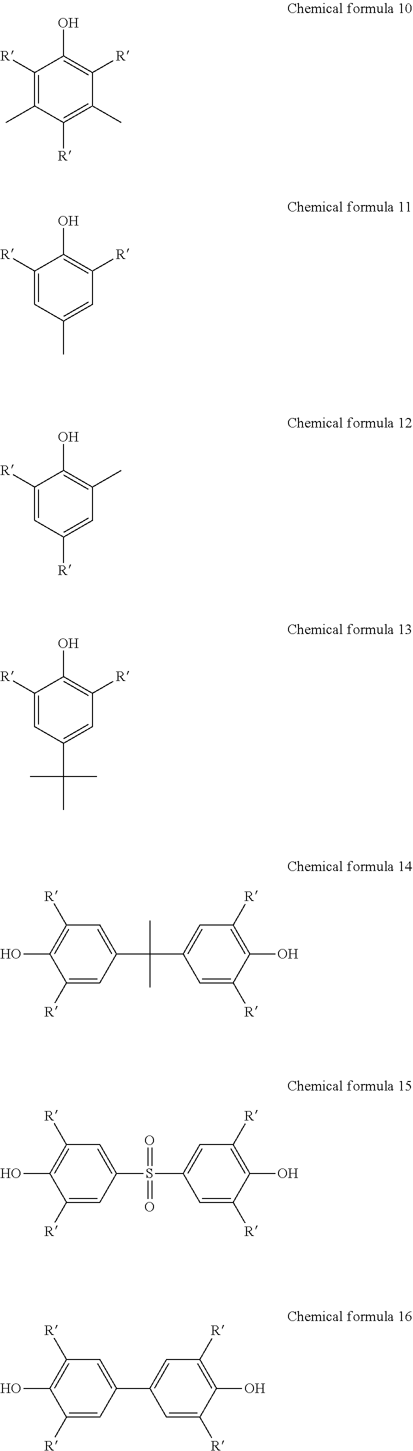

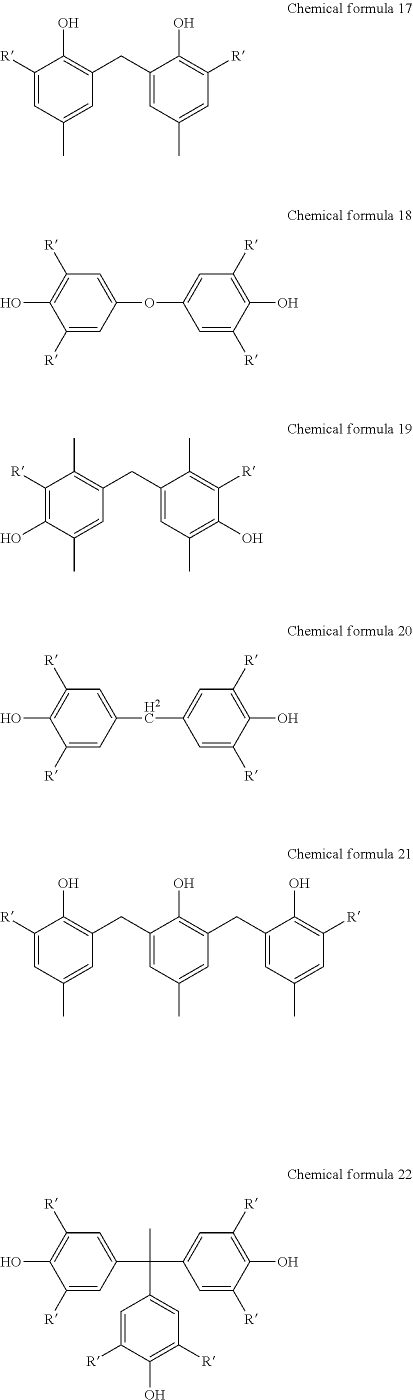

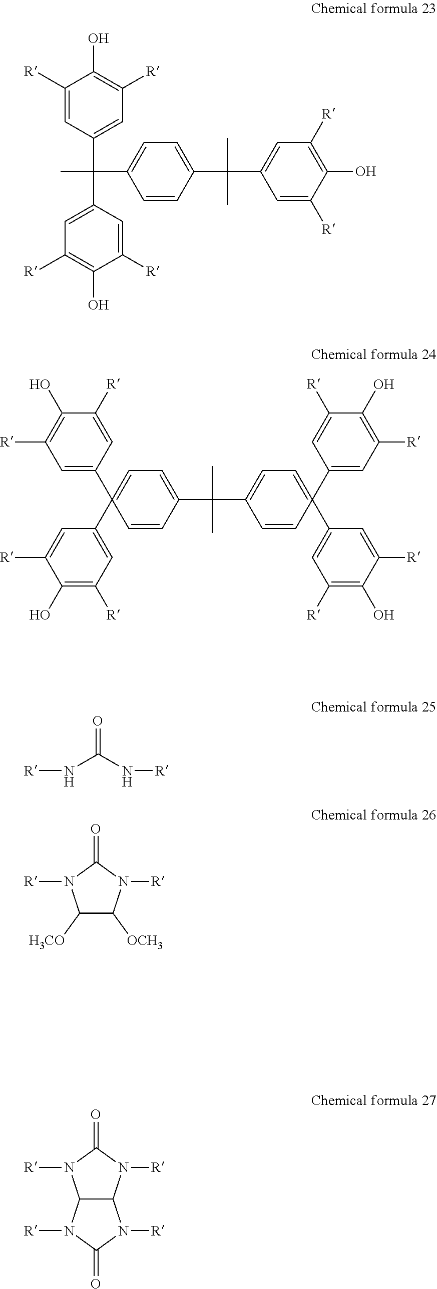

In Chemical Formulas 10 to 27, R′ are each independently one of a hydrogen atom, an alkyl group having 1 to 3 carbon atoms or one of substituents of Chemical Formula 28 below, at least one of R′ is a substituent of Chemical Formula 28 below, and in Chemical Formula 28 below, n is an integer of 1 to 6, and R₇ is an alkyl group having 1 to 3 carbon atoms.

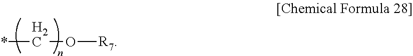

As the solvent, those that are used generally as a solvent for photosensitive resin compositions may be used, and examples thereof may include one or more selected from the group consisting of gamma-butyrolactone (GBL), N-Methyl-2-pyrrolidone (NMP), propylene glycol methyl ether acetate (PGMEA), ethyl lactate (EL), methyl 3-methoxypropionate (MMP), propylene glycol monomethyl ether (PGME), diethylene glycol methyl ethyl ether (MEDG), diethylene glycol butyl methyl ether (MBDG), diethylene glycol dimethyl ether (DMDG), diethylene glycol diethyl ether (DEDG), and mixtures thereof, but is not limited to the above examples.

According to another embodiment of the present disclosure, the positive-type photosensitive resin composition may further include one or more additives selected from the group consisting of a thermal acid generator and a UV absorber. With these additives included, heat resistance, hygroscopicity, and the like of the resin composition are improved so that it may have an effect of enabling more excellent panel reliability to be secured.

An insulating film according to another embodiment of the present disclosure includes a cured body of the positive-type photosensitive resin composition, and more specifically, the insulating film may be a surface protective film or an interlayer insulating film of an electronic component for semiconductors, but is not limited thereto.

Another embodiment of the present disclosure may be a display device including the insulating film, and a specific example may be a display device for an organic electroluminescent device. The display device for the organic electroluminescent device includes: a first electrode formed on a substrate; an insulating layer formed on the first electrode; and a second electrode formed on the insulating layer, and the insulating layer includes the positive-type photosensitive resin composition according to embodiments of the present disclosure.

The insulating layer may be patterned while partially exposing an upper surface of the first electrode. In addition, the insulating layer may be formed to cover an edge portion of the first electrode.

The insulating layer may be patterned while partially exposing an upper surface of the first electrode. In addition, the insulating layer may be formed to cover an edge portion of the first electrode.

Hereinafter, the present disclosure will be described in more detail through Examples, but the present disclosure is not limited by the following Examples.

### Preparation Example 1: First Polymer Synthesis

### Synthesis Example 1

After 80 mol of 2,2-Bis(3-amino-4-hydroxyphenyl)-hexafluoropropane and 20 mol of 1,3-Bis(4-aminophenoxy)Phenyl as diamines were dissolved in gamma butyrolactone under a dry nitrogen stream, 70 mol of dianhydride 4,4′-Oxydiphthalic Anhydride (ODPA) was added thereto while performing stirring and dissolved, and then stirred at 70° C. for 4 hours. Thereafter, 60 mol of phthalic anhydride (PA) was added thereto and stirred at 70° C. for 2 hours. Additionally, the reaction was terminated after performing stirring at 180° C. for 4 hours to obtain a polyimide polymer.

### Synthesis Example 2

A polyimide polymer was prepared in the same manner as in the Synthesis Example 1 except that 60 mol of 2,2-Bis(3-amino-4-hydroxyphenyl)propane and 40 mol of 4,4′-Oxydianiline were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 1.

### Synthesis Example 3

A polyimide polymer was prepared in the same manner as in the Synthesis Example 1 except that 50 mol of 2,2-Bis(3-amino-4-hydroxyphenyl)-hexafluoropropane and 50 mol of 1,3-Bis(4-aminophenoxy)Phenyl were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 1.

### Synthesis Example 4

A polyimide polymer was prepared in the same manner as in the Synthesis Example 1 except that 70 mol of 3,3′-Dihydroxy-4,4′-diamino-biphenyl and 30 mol of 1,3-Bis(3-aminophenoxy)benzene were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 1.

### Synthesis Example 5

A polyimide polymer was prepared in the same manner as in the Synthesis Example 1 except that 70 mol of 1,4-Bis(3,4-dicarboxyphenoxy)benzene dianhydride was used instead of 70 mol of 4,4′-Oxydiphthalic anhydride (ODPA) as a dianhydride in the Synthesis Example 1.

### Synthesis Example 6

After 80 mol of 2,2-Bis(3-amino-4-hydroxyphenyl)-hexafluoropropane and 20 mol of 1,3-Bis(4-aminophenoxy)Phenyl as diamines were dissolved in gamma butyrolactone under a dry nitrogen stream, 70 mol of dianhydride 4,4′-Oxydiphthalic Anhydride (ODPA) was added thereto while performing stirring and dissolved, and then stirred at 70° C. for 4 hours. Thereafter, 60 mol of phthalic anhydride (PA) was added thereto and stirred at 70° C. for 2 hours. After 30 mol of dimethylformamide dimethyl acetal (DFA) was added thereto and stirred at 180° C. for 4 hours, the reaction was terminated to obtain a polyimide polymer.

### Synthesis Example 7

A polyimide polymer was prepared in the same manner as in the Synthesis Example 6 except that 60 mol of 2,2-Bis(3-amino-4-hydroxyphenyl)propane and 40 mol of 4,4′-Oxydianiline were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 6.

### Synthesis Example 8

A polyimide polymer was prepared in the same manner as in the Synthesis Example 6 except that 50 mol of 2,2-Bis(3-amino-4-hydroxyphenyl)-hexafluoropropane and 50 mol of 1,3-Bis(4-aminophenoxy)Phenyl were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 6.

### Synthesis Example 9

A polyimide polymer was prepared in the same manner as in the Synthesis Example 6 except that 70 mol of 3,3′-Dihydroxy-4,4′-diamino-biphenyl and 30 mol of 1,3-Bis(3-aminophenoxy)benzene were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 6.

### Synthesis Example 10

A polyimide polymer was prepared in the same manner as in the Synthesis Example 6 except that 70 mol of 1,4-Bis(3,4-dicarboxyphenoxy)benzene dianhydride was used instead of 70 mol of 4,4′-Oxydiphthalic anhydride (ODPA) as a dianhydride in the Synthesis Example 6.

### Synthesis Example 11

70 mol of 2,2-Bis(3-amino-4-hydroxyphenyl)propane and 20 mol of 4,4′-Oxydianiline as diamines were dissolved in NMP under a dry nitrogen stream. 100 mol of dianhydride 4,4′-Oxydiphthalic Anhydride (ODPA) was added thereto and stirred at 30° C. for 2 hours. Thereafter, 20 mol of 3-aminophenol was added to continue stirring at 40° C. for 2 hours. In addition, pyridine was diluted to 20 wt % in toluene, added to the solution, and reaction was performed at a temperature of the solution of 120° C. for 2 hours or 180° C. for 2 hours while removing water along with toluene azeotropically in addition to the addition of the cooling tube. When the temperature of this solution decreased to room temperature, the solution was introduced into water to obtain a white powder. This powder was collected by filtration and further washed with water three times. After washing, the white powder was dried in a vacuum dryer at 50° C. for 72 hours. In this way, a polyimide polymer was obtained.

### Synthesis Example 12

A polyimide polymer was prepared in the same manner as in the Synthesis Example 11 except that 60 mol of 3,3′-Diamino-4,4′-dihydroxydiphenyl Sulfone and 30 mol of 4,4′-Oxydianiline were used instead of 70 mol of 2,2-Bis(3-amino-4-hydroxyphenyl)propane and 20 mol of 4,4′-Oxydianiline as diamines in the Synthesis Example 11.

### Synthesis Example 13

A polyimide polymer was prepared in the same manner as in the Synthesis Example 11 except that 50 mol of 2,2-Bis(3-amino-4-hydroxyphenyl)-hexafluoropropane and 40 mol of 1,3-Bis(4-aminophenoxy)Phenyl were used instead of 70 mol of 2,2-Bis(3-amino-4-hydroxyphenyl)propane and 20 mol of 4,4′-Oxydianiline as diamines in the Synthesis Example 11.

### Synthesis Example 14

A polyimide polymer was prepared in the same manner as in the Synthesis Example 11 except that 70 mol of 3,3′-Dihydroxy-4,4′-diamino-biphenyl and 20 mol of 1,3-Bis(3-aminophenoxy)benzene were used instead of 70 mol of 2,2-Bis(3-amino-4-hydroxyphenyl)propane and 20 mol of 4,4′-Oxydianiline as 2 diamines as a diamine in the Synthesis Example 11.

### Synthesis Example 15

A polyimide polymer was prepared in the same manner as in the Synthesis Example 11 except that 100 mol of 1,4-Bis(3,4-dicarboxyphenoxy)benzene dianhydride was used instead of 100 mol of 4,4′-Oxydiphthalic anhydride (ODPA) as a dianhydride in the Synthesis Example 11.

### Comparative Synthesis Example 1

A polyimide polymer was prepared in the same manner as in the Synthesis Example 1 except that 80 mol of 4,4′-Oxydianiline and 20 mol of 1,3-Bis(4-aminophenoxy)Phenyl were used instead of 80 mol of 2,2-Bis(3-amino-4-hydroxyphenyl)-hexafluoropropane and 20 mol of 1,3-Bis(4-aminophenoxy)Phenyl as diamines in the Synthesis Example 1.

### Preparation Example 2: Second Polymer Synthesis

### Synthesis Example 16

Under a dry nitrogen stream, 100 parts by weight of 2,2′-azobis(2,4-dimethylvaleronitrile) was added thereto after dissolving 100 mol of hydroxyphenyl maleimide in DMF. After the mixed solution was slowly raised to 55° C. and maintained at this temperature for 48 hours, it was cooled to room temperature, and tetrahydrofuran was completely removed through a drying process to obtain a polymer containing a hydroxyl group.

### Synthesis Example 17

A polymer containing a hydroxyl group was prepared in the same manner as in the Synthesis Example 16 except that 100 mol of hydroxyethyl maleimide was used instead of 100 mol of hydroxyphenyl maleimide as a monomer in the Synthesis Example 16.

### Synthesis Example 18

A polymer containing a hydroxyl group was prepared in the same manner as in the Synthesis Example 16 except that 50 mol of hydroxyphenyl maleimide and 50 mol of hydroxyethyl maleimide were used instead of 100 mol of hydroxyphenyl maleimide as monomers in the Synthesis Example 16.

### Synthesis Example 19

A polymer containing a hydroxyl group was prepared in the same manner as in the Synthesis Example 16 except that 80 mol of hydroxyphenyl maleimide and 20 mol of phenyl maleimide were used instead of 100 mol of hydroxyphenyl maleimide as a monomer in the Synthesis Example 16.

### Synthesis Example 20

A polymer containing a hydroxyl group was prepared in the same manner as in the Synthesis Example 16 except that 80 mol of hydroxyphenyl maleimide and 20 mol of styrene were used instead of 100 mol of hydroxyphenyl maleimide as a monomer in the Synthesis Example 16.

### Synthesis Example 21

A polymer containing a hydroxyl group was prepared in the same manner as in the Synthesis Example 16 except that 100 mol of hydroxy styrene was used instead of 100 mol of hydroxyphenyl maleimide as a monomer in the Synthesis Example 16.

### Synthesis Example 22

A polymer containing a hydroxyl group was prepared in the same manner as in the Synthesis Example 16 except that 50 mol of hydroxy styrene and 50 mol of hydroxyphenyl maleimide were used instead of 100 mol of hydroxyphenyl maleimide as a monomer in the Synthesis Example 16.

### Synthesis Example 23

A polymer containing a hydroxyl group was prepared in the same manner as in the Synthesis Example 16 except that 90 mol of hydroxy styrene and 10 mol of phenyl maleimide were used instead of 100 mol of hydroxyphenyl maleimide as a monomer in the Synthesis Example 16.

### Synthesis Example 24

A polymer containing a hydroxyl group was prepared in the same manner as in the Synthesis Example 16 except that 69 mol of hydroxyphenyl maleimide and 31 mol of phenyl maleimide were used instead of 100 mol of hydroxyphenyl maleimide as a monomer in the Synthesis Example 16.

### Synthesis Example 25

A polymer containing a hydroxyl group was prepared in the same manner as in the Synthesis Example 16 except that 65 mol of hydroxyphenyl maleimide and 35 mol of phenyl maleimide were used instead of 100 mol of hydroxyphenyl maleimide as a monomer in the Synthesis Example 16.

### Synthesis Example 26

A polymer containing a hydroxyl group was prepared in the same manner as in the Synthesis Example 16 except that 50 mol of hydroxyphenyl maleimide and 50 mol of phenyl maleimide were used instead of 100 mol of hydroxyphenyl maleimide as a monomer in the Synthesis Example 16.

### Synthesis Example 27

A polymer containing a hydroxyl group was prepared in the same manner as in the Synthesis Example 16 except that 30 mol of hydroxyphenyl maleimide and 70 mol of phenyl maleimide were used instead of 100 mol of hydroxyphenyl maleimide as a monomer in the Synthesis Example 16.

### Synthesis Example 28

A polymer containing a hydroxyl group was prepared in the same manner as in the Synthesis Example 16 except that 60 mol of hydroxy styrene and 40 mol of phenyl maleimide were used instead of 100 mol of hydroxyphenyl maleimide as a monomer in the Synthesis Example 16.

### Comparative Synthesis Example 2

After 193 g of phenol, 142 g of 37 wt % formalin, and 0.97 g (0.5%) of oxalic acid were introduced into a reactor under a dry nitrogen stream, and reacted at 100° C. for 6 hours, and then the product was concentrated under reduced pressure to obtain a novolac phenol resin.

### Preparation Example 3: Photosensitizer Synthesis

### Synthesis Example 29

1 mol of 4,4-[1-[4-[1-[4-hydroxyphenyl]-1-methylethyl]phenyl]ethylidene]bisphenol represented by Chemical Formula A below and 2 mol of 5-naphthoquinonediazidesulfonic acid chloride were dissolved by a ballast in 1,4-dioxane at room temperature under a dry nitrogen stream. Triethylamine was dropped thereto so as not to become 35° C. or more. After dropping, it was stirred at 40° C. for 2 hours. The triethylamine salt was filtered out, and filtrate was introduced into water. Thereafter, the precipitated precipitate was filtered and washed with 1% aqueous hydrochloric acid. After that, it was washed 3 times with water. This precipitate was dried with a vacuum dryer to prepare a quinonediazide compound.

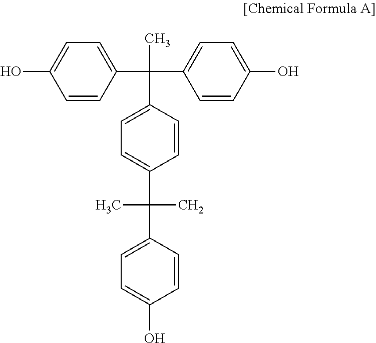 [SMILES: CC(C)(c1ccc(O)cc1)c1ccc(C(C)(c2ccc(O)cc2)c2ccc(O)cc2)cc1]

### Synthesis Example 30

A quinonediazide compound was prepared in the same manner as in the Synthesis Example 29 except that the material represented by Chemical Formula B below instead of 4,4-[1-[4-[1-[4-hydroxyphenyl]-1-methylethyl]phenyl]ethylidene]bisphenol was used by a ballast in the Synthesis Example 29.

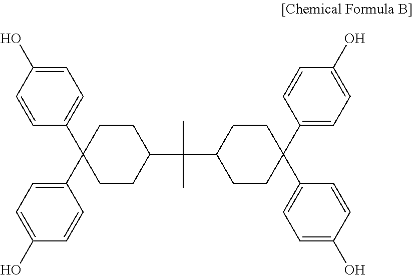 [SMILES: CC(C)(C1CCC(c2ccc(O)cc2)(c2ccc(O)cc2)CC1)C1CCC(c2ccc(O)cc2)(c2ccc(O)cc2)CC1]

### Synthesis Example 31

A quinonediazide compound was prepared in the same manner as in the Synthesis Example 29 except that the material represented by Chemical Formula C below instead of 4,4-[1-[4-[1-[4-hydroxyphenyl]-1-methylethyl]phenyl]ethylidene]bisphenol was used by a ballast in the Synthesis Example 29.

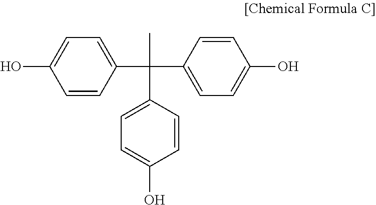 [SMILES: CC(c1ccc(O)cc1)(c1ccc(O)cc1)c1ccc(O)cc1]

### Preparation Example 4: Preparation of Photosensitive Polyimide Resin Composition

Resin compositions were prepared by mixing the compositions of Examples 1 to 48, Comparative Examples 1 to 4, and Reference Examples 1 to 14 according to the composition ratios of Tables 1 to 3 below.

TABLE 1

| | First polymer | | Second polymer | | Photosensitizer | | | |
|---|---|---|---|---|---|---|---|---|
| | | Content | | Content | | Content | Crosslinkable | |
| | | (parts by | | (parts by | | (parts by | compound | |
| Classification | Structure | weight) | Structure | weight) | Structure | weight) | Structure | Content |
| Example 1 | Synthesis | 95 | Synthesis | 5 | Synthesis | 5 | | skip |
| | Example 1 | | Example 16 | | Example 29 | | | |
| Example 2 | Synthesis | 90 | Synthesis | 10 | Synthesis | 10 | | skip |
| | Example 2 | | Example 17 | | Example 30 | | | |
| Example 3 | Synthesis | 80 | Synthesis | 20 | Synthesis | 15 | | skip |
| | Example 3 | | Example 18 | | Example 31 | | | |
| Example 4 | Synthesis | 70 | Synthesis | 30 | Synthesis | 20 | | skip |
| | Example 4 | | Example 19 | | Example 29 | | | |
| Example 5 | Synthesis | 60 | Synthesis | 40 | Synthesis | 25 | | skip |
| | Example 5 | | Example 20 | | Example 30 | | | |
| Example 6 | Synthesis | 50 | Synthesis | 50 | Synthesis | 30 | | skip |
| | Example 6 | | Example 21 | | Example 31 | | | |
| Example 7 | Synthesis | 95 | Synthesis | 5 | Synthesis | 35 | | skip |
| | Example 7 | | Example 22 | | Example 29 | | | |
| Example 8 | Synthesis | 90 | Synthesis | 10 | Synthesis | 40 | | skip |
| | Example 8 | | Example 23 | | Example 30 | | | |
| Example 9 | Synthesis | 80 | Synthesis | 20 | Synthesis | 45 | | skip |
| | Example 9 | | Example 16 | | Example 31 | | | |
| Example 10 | Synthesis | 70 | Synthesis | 30 | Synthesis | 50 | | skip |
| | Example 10 | | Example 17 | | Example 29 | | | |
| Example 11 | Synthesis | 60 | Synthesis | 40 | Synthesis | 5 | | skip |
| | Example 11 | | Example 18 | | Example 30 | | | |
| Example 12 | Synthesis | 50 | Synthesis | 50 | Synthesis | 10 | | skip |
| | Example 12 | | Example 19 | | Example 31 | | | |
| Example 13 | Synthesis | 95 | Synthesis | 5 | Synthesis | 15 | | skip |
| | Example 13 | | Example 20 | | Example 29 | | | |
| Example 14 | Synthesis | 90 | Synthesis | 10 | Synthesis | 20 | | skip |
| | Example 14 | | Example 21 | | Example 30 | | | |
| Example 15 | Synthesis | 80 | Synthesis | 20 | Synthesis | 25 | | skip |
| | Example 15 | | Example 22 | | Example 31 | | | |
| Example 16 | Synthesis | 70 | Synthesis | 30 | Synthesis | 30 | | skip |
| | Example 1 | | Example 23 | | Example 29 | | | |
| Example 17 | Synthesis | 60 | Synthesis | 40 | Synthesis | 35 | | skip |
| | Example 2 | | Example 16 | | Example 30 | | | |
| Example 18 | Synthesis | 50 | Synthesis | 50 | Synthesis | 40 | | skip |
| | Example 3 | | Example 17 | | Example 31 | | | |
| Example 19 | Synthesis | 95 | Synthesis | 5 | Synthesis | 45 | | skip |
| | Example 4 | | Example 18 | | Example 29 | | | |
| Example 20 | Synthesis | 90 | Synthesis | 10 | Synthesis | 50 | | skip |
| | Example 5 | | Example 19 | | Example 30 | | | |
| Example 21 | Synthesis | 80 | Synthesis | 20 | Synthesis | 5 | | skip |
| | Example 6 | | Example 20 | | Example 31 | | | |
| Example 22 | Synthesis | 70 | Synthesis | 30 | Synthesis | 10 | | skip |
| | Example 7 | | Example 21 | | Example 29 | | | |
| Example 23 | Synthesis | 60 | Synthesis | 40 | Synthesis | 15 | | skip |
| | Example 8 | | Example 22 | | Example 30 | | | |
| Example 24 | Synthesis | 50 | Synthesis | 50 | Synthesis | 20 | | skip |
| | Example 9 | | Example 23 | | Example 31 | | | |
| Example 25 | Synthesis | 95 | Synthesis | 5 | Synthesis | 25 | | skip |
| | Example 10 | | Example 16 | | Example 29 | | | |
| Example 26 | Synthesis | 90 | Synthesis | 10 | Synthesis | 30 | | skip |
| | Example 11 | | Example 17 | | Example 30 | | | |
| Example 27 | Synthesis | 80 | Synthesis | 20 | Synthesis | 35 | | skip |
| | Example 12 | | Example 18 | | Example 31 | | | |
| Example 28 | Synthesis | 70 | Synthesis | 30 | Synthesis | 40 | | skip |
| | Example 13 | | Example 19 | | Example 29 | | | |
| Example 29 | Synthesis | 60 | Synthesis | 40 | Synthesis | 45 | | skip |
| | Example 14 | | Example 20 | | Example 30 | | | |
| Example 30 | Synthesis | 50 | Synthesis | 50 | Synthesis | 50 | | skip |
| | Example 15 | | Example 21 | | Example 31 | | | |

TABLE 2

| | | | | | | | Crosslinkable | |
|---|---|---|---|---|---|---|---|---|
| | First polymer | | Second polymer | | Photosensitizer | | compound | |
| | | Content | | Content | | Content | | Content |
| | | (parts by | | (parts by | | (parts by | | (parts by |
| Classification | Structure | weight) | Structure | weight) | Structure | weight) | Structure | weight) |
| Example 31 | Synthesis | 95 | Synthesis | 5 | Synthesis | 5 | Chemical | 5 |
| | Example 1 | | Example 22 | | Example 29 | | Formula D | |
| Example 32 | Synthesis | 90 | Synthesis | 10 | Synthesis | 10 | Chemical | 10 |
| | Example 2 | | Example 23 | | Example 30 | | Formula E | |
| Example 33 | Synthesis | 80 | Synthesis | 20 | Synthesis | 15 | Chemical | 15 |
| | Example 3 | | Example 16 | | Example 31 | | Formula F | |
| Example 34 | Synthesis | 70 | Synthesis | 30 | Synthesis | 20 | Chemical | 20 |
| | Example 4 | | Example 17 | | Example 29 | | Formula D | |
| Example 35 | Synthesis | 60 | Synthesis | 40 | Synthesis | 25 | Chemical | 25 |
| | Example 5 | | Example 18 | | Example 30 | | Formula E | |
| Example 36 | Synthesis | 50 | Synthesis | 50 | Synthesis | 30 | Chemical | 5 |
| | Example 6 | | Example 19 | | Example 31 | | Formula F | |
| Example 37 | Synthesis | 95 | Synthesis | 5 | Synthesis | 35 | Chemical | 10 |
| | Example 7 | | Example 20 | | Example 29 | | Formula D | |
| Example 38 | Synthesis | 90 | Synthesis | 10 | Synthesis | 40 | Chemical | 15 |
| | Example 8 | | Example 21 | | Example 30 | | Formula E | |
| Example 39 | Synthesis | 80 | Synthesis | 20 | Synthesis | 45 | Chemical | 20 |
| | Example 9 | | Example 22 | | Example 31 | | Formula F | |
| Example 40 | Synthesis | 70 | Synthesis | 30 | Synthesis | 50 | Chemical | 25 |
| | Example 10 | | Example 23 | | Example 29 | | Formula D | |
| Example 41 | Synthesis | 60 | Synthesis | 40 | Synthesis | 10 | Chemical | 5 |
| | Example 11 | | Example 16 | | Example 30 | | Formula E | |
| Example 42 | Synthesis | 50 | Synthesis | 50 | Synthesis | 15 | Chemical | 10 |
| | Example 12 | | Example 17 | | Example 31 | | Formula F | |
| Example 43 | Synthesis | 95 | Synthesis | 5 | Synthesis | 20 | Chemical | 15 |
| | Example 13 | | Example 18 | | Example 29 | | Formula D | |
| Example 44 | Synthesis | 90 | Synthesis | 10 | Synthesis | 25 | Chemical | 20 |
| | Example 14 | | Example 19 | | Example 30 | | Formula E | |
| Example 45 | Synthesis | 80 | Synthesis | 20 | Synthesis | 30 | Chemical | 25 |
| | Example 15 | | Example 20 | | Example 31 | | Formula F | |
| Example 46 | Synthesis | 70 | Synthesis | 30 | Synthesis | 35 | Chemical | 5 |
| | Example 1 | | Example 21 | | Example 29 | | Formula D | |
| Example 47 | Synthesis | 60 | Synthesis | 40 | Synthesis | 40 | Chemical | 10 |
| | Example 6 | | Example 22 | | Example 30 | | Formula E | |
| Example 48 | Synthesis | 50 | Synthesis | 50 | Synthesis | 45 | Chemical | 15 |
| | Example 11 | | Example 23 | | Example 31 | | Formula F | |

In Table 2, Chemical Formula D to Chemical Formula F, which are crosslinkable compounds, are compounds represented as follows.

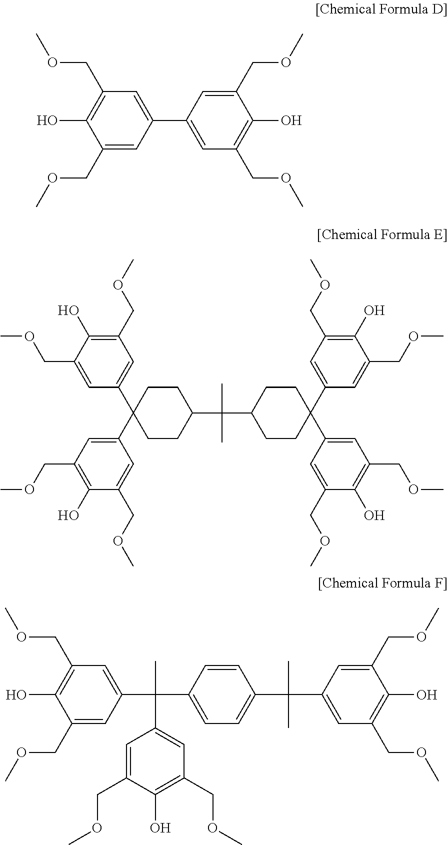

TABLE 3

| | First polymer | | Second polymer | | Photosensitizer | | | |
|---|---|---|---|---|---|---|---|---|
| | | Content | | Content | | Content | Crosslinkable | |
| | | (parts by | | (parts by | | (parts by | compound | |
| Classification | Structure | weight) | Structure | weight) | Structure | weight) | Structure | Content |
| Comparative | Synthesis | 100 | | skip | Synthesis | 50 | | skip |
| Example 1 | Example 1 | | | | Example 29 | | | |
| Comparative | Synthesis | 100 | | skip | Synthesis | 45 | | skip |
| Example 2 | Example 6 | | | | Example 30 | | | |
| Comparative | Synthesis | 100 | | skip | Synthesis | 40 | | skip |
| Example 3 | Example 11 | | | | Example 31 | | | |
| Comparative | | skip | Synthesis | 100 | Synthesis | 30 | | skip |
| Example 4 | | | Example 16 | | Example 29 | | | |
| Reference | Synthesis | 10 | Synthesis | 90 | Synthesis | 20 | | skip |
| Example 1 | Example 6 | | Example 17 | | Example 30 | | | |
| Reference | Synthesis | 20 | Synthesis | 80 | Synthesis | 30 | | skip |
| Example 2 | Example 11 | | Example 18 | | Example 31 | | | |
| Reference | Synthesis | 30 | Synthesis | 70 | Synthesis | 5 | | skip |
| Example 3 | Example 1 | | Example 19 | | Example 29 | | | |
| Reference | Synthesis | 40 | Synthesis | 60 | Synthesis | 10 | | skip |
| Example 4 | Example 6 | | Example 20 | | Example 30 | | | |
| Reference | Synthesis | 49 | Synthesis | 51 | Synthesis | 15 | | skip |
| Example 5 | Example 11 | | Example 21 | | Example 31 | | | |
| Reference | Synthesis | 96 | Synthesis | 4 | Synthesis | 20 | | skip |
| Example 6 | Example 1 | | Example 22 | | Example 29 | | | |
| Reference | Synthesis | 95 | Synthesis | 5 | Synthesis | 25 | | skip |
| Example 7 | Example 6 | | Example 24 | | Example 30 | | | |
| Reference | Synthesis | 90 | Synthesis | 10 | Synthesis | 30 | | skip |
| Example 8 | Example 11 | | Example 25 | | Example 31 | | | |
| Reference | Synthesis | 80 | Synthesis | 20 | Synthesis | 35 | | skip |
| Example 9 | Example 1 | | Example 26 | | Example 29 | | | |
| Reference | Synthesis | 70 | Synthesis | 30 | Synthesis | 40 | | skip |
| Example 10 | Example 6 | | Example 27 | | Example 30 | | | |
| Reference | Synthesis | 60 | Synthesis | 40 | Synthesis | 45 | | skip |
| Example 11 | Example 11 | | Example 28 | | Example 31 | | | |
| Reference | Synthesis | 80 | Synthesis | 20 | Synthesis | 4 | | skip |
| Example 12 | Example 1 | | Example 16 | | Example 29 | | | |
| Reference | Synthesis | 70 | Synthesis | 30 | Synthesis | 51 | | skip |
| Example 13 | Example 6 | | Example 17 | | Example 30 | | | |
| Reference | Synthesis | 60 | Synthesis | 40 | Synthesis | 55 | | skip |
| Example 14 | Example 11 | | Example 18 | | Example 31 | | | |

### Experimental Example 1: Evaluation of Physical Properties of Photosensitive Polyimide Resin Compositions

For Examples 1 to 48, Comparative Examples 1 to 4, and Reference Examples 1 to 14 prepared according to Preparation Example 4 above, physical properties such as sensitivity, film thickness retention rate, adhesive force, chemical resistance, heat resistance, hygroscopicity, driving reliability, and the like were measured based on the following criteria and are shown in Tables 4 to 6 and 8 below. After applying the photosensitive resin composition in Examples 1 to 48, Comparative Examples 1 to 4, and Reference Examples 1 to 14 using a slit coater on a glass substrate, a vacuum drying (VCD) process was performed to a pressure of 40 Pa and prebaked on a hot plate at 120° C. for 2 minutes to form a film having a thickness of 3.0 μm.

A) Sensitivity

After ultraviolet rays having an intensity of 20 mW/cm² in broadband were irradiated to the film formed as described above with a sensitivity of 2.5 μm contact hole CD standard dose using a predetermined pattern mask, it was developed with an aqueous solution of 2.38 wt % of tetramethyl ammonium hydroxide at 23° C. for 1 minute, and then washed with ultrapure water for 1 minute. Then, it was cured in an oven at 250° C. for 60 minutes to obtain a patterned film having a thickness of 2.0 μm. The case where the sensitivity was 100 mJ or less was marked as ◯, the case where the sensitivity was more than 100 mJ to 120 mJ or less was marked as Δ, and the case where the sensitivity was more than 120 mJ was marked as ×.

B) Film Thickness Retention Rate

The film thickness changes during the sensitivity measurements of A) were measured.

The film thickness retention rate or ratio can be defined as the thickness of the film after curing/thickness after prebaking, and the case where the film thickness retention rate was 60% or more was marked as ∘, the case where the film thickness retention rate was 50% or more to less than 60% was marked as Δ, and the case where the film thickness retention rate was less than 50% was marked as ×.

C) Adhesive Force

Pattern films were formed in the same manner as when measuring the sensitivities of A), but the adhesive forces were compared and evaluated based on the minimum CD of the attached dot patterns. The case where the adhesive force was secured at the dot pattern minimum CD of 5 μm or more was marked as ∘, the case where the adhesive force was secured at the dot pattern minimum CD of 10 μm or more was marked as Δ, and the case where the adhesive force was secured or not at the dot pattern minimum CD of 15 μm or more was marked as ×.

D) Chemical Resistance

The prepared substrate was immersed in methylpyrrolidone (NMP) at 60° C. for 120 seconds, and the cured film thickness change rates before and after immersion were measured. A cured film thickness change rate of less than 150 Å was marked as ⊚, a cured film thickness change rate of 150 Å or more to less than 300 Å was marked as ◯, a cured film thickness change rate of 300 Å or more to less than 600 Å was marked as Δ, and a cured film thickness change rate of 600 Å or more was marked as ×.
E) Heat Resistance

Heat resistance was measured using thermogravimetric analysis (TGA). After sampling the pattern films formed during the sensitivity measurement in A), the temperature was raised from room temperature to 900° C. at a rate of 10° C. per minute using TGA. The case where the 5 wt % loss temperature was more than 300° C. was marked as ◯, the case where the 5 wt % loss temperature was 280 to 300° C. was marked as Δ, and the case where the 5 wt % loss temperature was less than 280° C. was marked as ×.

F) Hygroscopicity

After purifying the pattern films formed during the sensitivity measurement of A) in a constant temperature, constant humidity oven at 85° C. and 85% RH standard for 240 hours, hygroscopicity was evaluated based on the film thickness changes of before and after introducing the films into the oven. The case where the thickness change rate was less than 250 Å was marked as ⊚, the case where the thickness change rate was more than 250 Å to less than 300 Å was marked as ◯, the case where the thickness change rate was 300 Å or more to less than 600 Å was marked as Δ, and the case where the thickness change rate was 600 Å or more was marked as ×.

G) OLED Driving Reliability

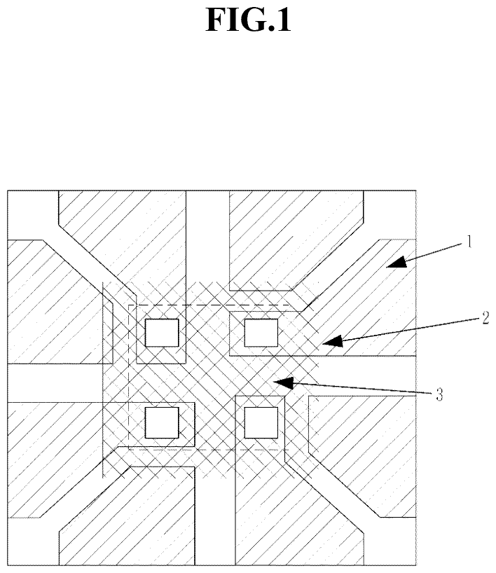

FIG. 1 schematically shows that a pattern film 2 is formed on an indium tin oxide (ITO) substrate 1 on which a pattern according to an embodiment of the present disclosure is formed, and electroluminescent lighting (EL) and aluminum 3 are deposited thereon. A pattern film is formed on the patterned ITO substrate shown in FIG. 1 in the same manner as the sensitivity measurement method of A) above, and EL is deposited thereon. Al as a cathode electrode is deposited on the top, and the encapsulation process is proceeded. The time (T₉₇) it takes for the luminance to drop by 3% was evaluated at 85° C. and 85% RH standard and in the device On state. The case where 1,100 hours or more were secured was marked as ⊚, the case where 1,000 hours or more to less than 1,100 hours were secured was marked as ◯, the case where 900 to 1,000 hours were secured was marked as Δ, and the case where less than 900 hours were secured was marked as ×.

TABLE 4

| | Evaluation | | | | | | |
|---|---|---|---|---|---|---|---|
| | A) | B) | C) | D) | E) | F) | G) |
| | Classification | | | | | | |
| | | Film | | | | | |
| | | thickness | | | | | |
| | | retention | Adhesive | Chemical | Heat | | Driving |
| | Sensitivity | rate | force | resistance | resistance | Hygroscopicity | reliability |
| Example 1 | ◯ | ◯ | ◯ | ◯ | ◯ | ◯ | ◯ |
| Example 2 | ◯ | ◯ | ◯ | ◯ | ◯ | ◯ | ◯ |
| Example 3 | ◯ | ◯ | ◯ | ◯ | ◯ | ◯ | ◯ |
| Example 4 | ◯ | ◯ | ◯ | ◯ | ◯ | ◯ | ◯ |
| Example 5 | ◯ | ◯ | ◯ | ◯ | ◯ | ◯ | ◯ |
| Example 6 | ◯ | ◯ | ◯ | ◯ | ◯ | ◯ | ◯ |
| Example 7 | ◯ | ◯ | ◯ | ◯ | ◯ | ◯ | ◯ |
| Example 8 | ◯ | ◯ | ◯ | ◯ | ◯ | ◯ | ◯ |
| Example 9 | ◯ | ◯ | ◯ | ◯ | ◯ | ◯ | ◯ |
| Example 10 | ◯ | ◯ | ◯ | ◯ | ◯ | ◯ | ◯ |
| Example 11 | ◯ | ◯ | ◯ | ◯ | ◯ | ◯ | ◯ |
| Example 12 | ◯ | ◯ | ◯ | ◯ | ◯ | ◯ | ◯ |
| Example 13 | ◯ | ◯ | ◯ | ◯ | ◯ | ◯ | ◯ |
| Example 14 | ◯ | ◯ | ◯ | ◯ | ◯ | ◯ | ◯ |
| Example 15 | ◯ | ◯ | ◯ | ◯ | ◯ | ◯ | ◯ |
| Example 16 | ◯ | ◯ | ◯ | ◯ | ◯ | ◯ | ◯ |
| Example 17 | ◯ | ◯ | ◯ | ◯ | ◯ | ◯ | ◯ |
| Example 18 | ◯ | ◯ | ◯ | ◯ | ◯ | ◯ | ◯ |
| Example 19 | ◯ | ◯ | ◯ | ◯ | ◯ | ◯ | ◯ |
| Example 20 | ◯ | ◯ | ◯ | ◯ | ◯ | ◯ | ◯ |
| Example 21 | ◯ | ◯ | ◯ | ◯ | ◯ | ◯ | ◯ |
| Example 22 | ◯ | ◯ | ◯ | ◯ | ◯ | ◯ | ◯ |
| Example 23 | ◯ | ◯ | ◯ | ◯ | ◯ | ◯ | ◯ |
| Example 24 | ◯ | ◯ | ◯ | ◯ | ◯ | ◯ | ◯ |
| Example 25 | ◯ | ◯ | ◯ | ◯ | ◯ | ◯ | ◯ |
| Example 26 | ◯ | ◯ | ◯ | ◯ | ◯ | ◯ | ◯ |
| Example 27 | ◯ | ◯ | ◯ | ◯ | ◯ | ◯ | ◯ |
| Example 28 | ◯ | ◯ | ◯ | ◯ | ◯ | ◯ | ◯ |
| Example 29 | ◯ | ◯ | ◯ | ◯ | ◯ | ◯ | ◯ |
| Example 30 | ◯ | ◯ | ◯ | ◯ | ◯ | ◯ | ◯ |

TABLE 5

| | Evaluation | | | | | | |
|---|---|---|---|---|---|---|---|
| | A) | B) | C) | D) | E) | F) | G) |
| | Classification | | | | | | |
| | | Film | | | | | |
| | | thickness | | | | | |
| | | retention | Adhesive | Chemical | Heat | | Driving |
| | Sensitivity | rate | force | resistance | resistance | Hygroscopicity | reliability |
| Example 31 | ◯ | ◯ | ◯ | ⊚ | ◯ | ◯ | ◯ |
| Example 32 | ◯ | ◯ | ◯ | ⊚ | ◯ | ◯ | ◯ |
| Example 33 | ◯ | ◯ | ◯ | ⊚ | ◯ | ◯ | ◯ |
| Example 34 | ◯ | ◯ | ◯ | ⊚ | ◯ | ◯ | ◯ |
| Example 35 | ◯ | ◯ | ◯ | ⊚ | ◯ | ◯ | ◯ |
| Example 36 | ◯ | ◯ | ◯ | ⊚ | ◯ | ◯ | ◯ |
| Example 37 | ◯ | ◯ | ◯ | ⊚ | ◯ | ◯ | ◯ |
| Example 38 | ◯ | ◯ | ◯ | ⊚ | ◯ | ◯ | ◯ |
| Example 39 | ◯ | ◯ | ◯ | ⊚ | ◯ | ◯ | ◯ |
| Example 40 | ◯ | ◯ | ◯ | ⊚ | ◯ | ◯ | ◯ |
| Example 41 | ◯ | ◯ | ◯ | ⊚ | ◯ | ◯ | ◯ |
| Example 42 | ◯ | ◯ | ◯ | ⊚ | ◯ | ◯ | ◯ |
| Example 43 | ◯ | ◯ | ◯ | ⊚ | ◯ | ◯ | ◯ |
| Example 44 | ◯ | ◯ | ◯ | ⊚ | ◯ | ◯ | ◯ |
| Example 45 | ◯ | ◯ | ◯ | ⊚ | ◯ | ◯ | ◯ |
| Example 46 | ◯ | ◯ | ◯ | ⊚ | ◯ | ◯ | ◯ |
| Example 47 | ◯ | ◯ | ◯ | ⊚ | ◯ | ◯ | ◯ |
| Example 48 | ◯ | ◯ | ◯ | ⊚ | ◯ | ◯ | ◯ |

TABLE 6

| | Evaluation | | | | | | |
|---|---|---|---|---|---|---|---|
| | A) | B) | C) | D) | E) | F) | G) |
| | Classification | | | | | | |
| | | Film | | | | | |
| | | thickness | | | | | |
| | | retention | Adhesive | Chemical | Heat | | Driving |
| | Sensitivity | rate | force | resistance | resistance | Hygroscopicity | reliability |
| Comparative | X | ◯ | ◯ | ◯ | ◯ | ◯ | ◯ |
| Example 1 | | | | | | | |
| Comparative | X | ◯ | ◯ | ◯ | ◯ | ◯ | ◯ |
| Example 2 | | | | | | | |
| Comparative | X | ◯ | ◯ | ◯ | ◯ | ◯ | ◯ |
| Example 3 | | | | | | | |
| Comparative | ◯ | X | X | X | X | X | X |
| Example 4 | | | | | | | |
| Reference | ◯ | Δ | Δ | Δ | Δ | Δ | Δ |
| Example 1 | | | | | | | |
| Reference | ◯ | Δ | Δ | Δ | Δ | Δ | Δ |
| Example 2 | | | | | | | |
| Reference | ◯ | Δ | Δ | Δ | Δ | Δ | Δ |
| Example 3 | | | | | | | |
| Reference | ◯ | Δ | Δ | Δ | Δ | Δ | Δ |
| Example 4 | | | | | | | |
| Reference | ◯ | Δ | Δ | Δ | Δ | Δ | Δ |
| Example 5 | | | | | | | |
| Reference | Δ | ◯ | ◯ | ◯ | ◯ | ◯ | ◯ |
| Example 6 | | | | | | | |
| Reference | Δ | ◯ | ◯ | ◯ | ◯ | ◯ | ◯ |
| Example 7 | | | | | | | |
| Reference | Δ | ◯ | ◯ | ◯ | ◯ | ◯ | ◯ |
| Example 8 | | | | | | | |
| Reference | Δ | ◯ | ◯ | ◯ | ◯ | ◯ | ◯ |
| Example 9 | | | | | | | |
| Reference | Δ | ◯ | ◯ | ◯ | ◯ | ◯ | ◯ |
| Example 10 | | | | | | | |
| Reference | Δ | ◯ | ◯ | ◯ | ◯ | ◯ | ◯ |
| Example 11 | | | | | | | |
| Reference | Δ | Δ | ◯ | ◯ | ◯ | ◯ | ◯ |
| Example 12 | | | | | | | |
| Reference | Δ | ◯ | ◯ | ◯ | ◯ | ◯ | ◯ |
| Example 13 | | | | | | | |
| Reference | Δ | ◯ | ◯ | ◯ | ◯ | ◯ | ◯ |
| Example 14 | | | | | | | |

### Experimental Example 2: Evaluation of Physical Properties of Photosensitive Polyimide Resin Compositions According to Hydroxyl Group Equivalent Ratios

After preparing resin compositions by mixing according to the composition ratios of Table 7 below, evaluation of physical properties such as sensitivity and the like was performed in the same manner as in the Experimental Example 1. The unit of content in Table 7 below is parts by weight.

TABLE 7

| | | | | | | | | | Hydroxyl |
|---|---|---|---|---|---|---|---|---|---|
| | | | | | | | | | equivalent ratio |
| | | | | | | | | | of the first |
| | | | | | | | Crosslinkable | | polymer and |
| | First polymer | | Second polymer | | Photosensitizer | | compound | | the second |
| | Structure | Content | Structure | Content | Structure | Content | Structure | Content | polymer |
| Example 49 | Synthesis | 95 | Synthesis | 5 | Synthesis | 15 | Chemical | 15 | 1:0.7 |
| | Example 1 | | Example 16 | | Example 31 | | Formula F | | |
| Example 50 | Synthesis | 90 | Synthesis | 10 | Synthesis | 15 | Chemical | 15 | 1:1.5 |
| | Example 2 | | Example 17 | | Example 31 | | Formula F | | |
| Example 51 | Synthesis | 80 | Synthesis | 20 | Synthesis | 15 | Chemical | 15 | 1:3.4 |
| | Example 3 | | Example 18 | | Example 31 | | Formula F | | |
| Example 52 | Synthesis | 70 | Synthesis | 30 | Synthesis | 15 | Chemical | 15 | 1:5.8 |
| | Example 4 | | Example 19 | | Example 31 | | Formula F | | |
| Example 53 | Synthesis | 60 | Synthesis | 40 | Synthesis | 15 | Chemical | 15 | 1:9 |
| | Example 5 | | Example 20 | | Example 31 | | Formula F | | |
| Example 54 | Synthesis | 50 | Synthesis | 50 | Synthesis | 15 | Chemical | 15 | 1:13.5 |
| | Example 6 | | Example 21 | | Example 31 | | Formula F | | |
| Comparative | Comparative | 80 | Synthesis | 20 | Synthesis | 15 | Chemical | 15 | 0:57.5 |
| Example 5 | Synthesis | | Example 16 | | Example 31 | | Formula F | | |
| | Example 1 | | | | | | | | |
| Comparative | Synthesis | 100 | Comparative | 0 | Synthesis | 15 | Chemical | 15 | 7:0 |
| Example 6 | Example 1 | | Synthesis | | Example 31 | | Formula F | | |
| | | | Example 2 | | | | | | |
| Comparative | Synthesis | 42 | Comparative | 58 | Synthesis | 15 | Chemical | 15 | 1:74.6 |
| Example 7 | Example 1 | | Synthesis | | Example 31 | | Formula F | | |
| | | | Example 2 | | | | | | |
| Comparative | Synthesis | 40 | Comparative | 60 | Synthesis | 15 | Chemical | 15 | 1:107.3 |
| Example 8 | Example 1 | | Synthesis | | Example 31 | | Formula F | | |
| | | | Example 2 | | | | | | |
| Comparative | Synthesis | 30 | Comparative | 70 | Synthesis | 15 | Chemical | 15 | 1:166.8 |
| Example 9 | Example 1 | | Synthesis | | Example 31 | | Formula F | | |
| | | | Example 2 | | | | | | |
| Comparative | Synthesis | 20 | Comparative | 80 | Synthesis | 15 | Chemical | 15 | 1:216.0 |
| Example 10 | Example 1 | | Synthesis | | Example 31 | | Formula F | | |
| | | | Example 2 | | | | | | |

TABLE 8

| | | Film | | | | | |
|---|---|---|---|---|---|---|---|
| | | thickness | | | | | |
| | | retention | Adhesive | Chemical | Heat | | Driving |
| | Sensitivity | rate | force | resistance | resistance | Hygroscopicity | reliability |
| Example 49 | ◯ | ◯ | ◯ | ◯ | ◯ | ⊚ | ⊚ |
| Example 50 | ◯ | ◯ | ◯ | ◯ | ◯ | ⊚ | ⊚ |
| Example 51 | ◯ | ◯ | ◯ | ◯ | ◯ | ⊚ | ⊚ |
| Example 52 | ◯ | ◯ | ◯ | ◯ | ◯ | ◯ | ◯ |
| Example 53 | ◯ | ◯ | ◯ | ◯ | ◯ | ◯ | ◯ |
| Example 54 | ◯ | ◯ | ◯ | ◯ | ◯ | ◯ | ◯ |
| Comparative | X | X | ◯ | X | ◯ | ◯ | ◯ |
| Example 5 | | | | | | | |
| Comparative | X | ◯ | ◯ | X | ◯ | ◯ | ◯ |
| Example 6 | | | | | | | |
| Comparative | X | X | ◯ | X | ◯ | ◯ | ◯ |
| Example 7 | | | | | | | |
| Comparative | X | X | ◯ | X | ◯ | ◯ | ◯ |
| Example 8 | | | | | | | |
| Comparative | X | X | ◯ | X | ◯ | ◯ | ◯ |
| Example 9 | | | | | | | |
| Comparative | ◯ | ◯ | ◯ | ◯ | X | X | X |
| Example 10 | | | | | | | |

As described in Table 8, when the first polymer does not contain a hydroxyl group and thus the hydroxyl group equivalent ratio of the first polymer and the second polymer is low, there was a problem that the sensitivity is significantly lowered. In addition, when the hydroxyl equivalent content of the second polymer is excessive, the sensitivity was improved, but there was a problem that chemical resistance or heat resistance is significantly deteriorated, and there was a problem that moisture absorption and driving reliability were also deteriorated. On the other hand, it can be seen that Examples 49 to 54 in which the hydroxyl equivalent ratio of the first polymer and the second polymer is adjusted to an appropriate level not only have excellent sensitivity, but also have excellent heat resistance, driving reliability, etc.

Although the preferred embodiments of the present disclosure have been described in detail above, the scope of rights of the present disclosure is not limited thereto, and various modifications and improved forms of those skilled in the art using the basic concept of the present disclosure defined in the following claims also fall within the scope of the rights of the present disclosure.

1. A positive-type photosensitive resin composition comprising:
a first polymer comprising one or more structures selected from the group consisting of polyamic acid ester, polyamic acid, and polyimide;
a second polymer containing at least one hydroxyl group among repeating units;
a photosensitizer; and
a solvent,
wherein a hydroxyl group equivalent ratio of the first polymer to the second polymer is 1:0.04 to 1:74.

2. The positive-type photosensitive resin composition of claim 1, wherein the second polymer contains one or more repeating units represented by the following Chemical Formula 1 or 2: 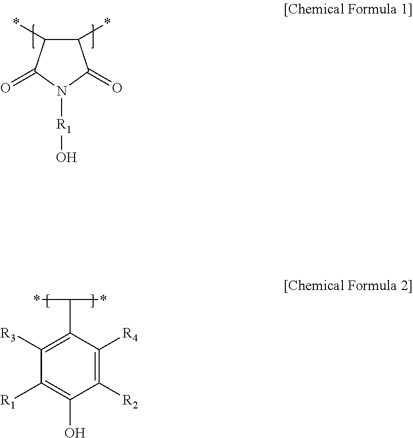
wherein, in Chemical Formula 1, R₁ is an organic group having 1 to 20 carbon atoms,
wherein, in Chemical Formula 2, R₁ to R₄ are each independently hydrogen, an organic group having 1 to 30 carbon atoms, or a substituent of Chemical Formula 3 below: [symbol]
(CH₂)ₘ—O—R₅) [Chemical Formula 3]
wherein, in Chemical Formula 3, R₅ is an alkyl group having 1 to 3 carbon atoms, and m is an integer of 1 or 2.

3. The positive-type photosensitive resin composition of claim 2, wherein at least one of R₁ to R₄ in Chemical Formula 2 includes a substituent of Chemical Formula 3.

4. The positive-type photosensitive resin composition of claim 2, wherein the second polymer contains the repeating unit represented by Chemical Formula 1 and does not contain the repeating unit represented by Chemical Formula 2.

5. The positive-type photosensitive resin composition of claim 2, wherein the second polymer contains two or more types of repeating units represented by Chemical Formula 1 in which R₁ has different structures.

6. The positive-type photosensitive resin composition of claim 2, wherein the second polymer contains one or more of:
a repeating unit represented by Chemical Formula 1 in which R₁ includes an aromatic ring structure; and
a repeating unit represented by Chemical Formula 1 in which R₁ includes no aromatic ring structure.

7. The positive-type photosensitive resin composition of claim 2, wherein Chemical Formula 1 contains one or more of a repeating unit represented by the following Chemical Formula 4 and a repeating unit represented by Chemical Formula 5: 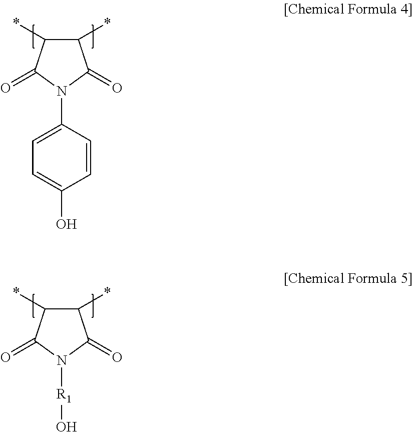
wherein, in Chemical Formula 5, R₁ is an aliphatic organic group having 1 to 20 carbon atoms.

8. The positive-type photosensitive resin composition of claim 2, wherein the second polymer further contains one or more types of repeating units among repeating units represented by the following Chemical Formula 6 or 7: 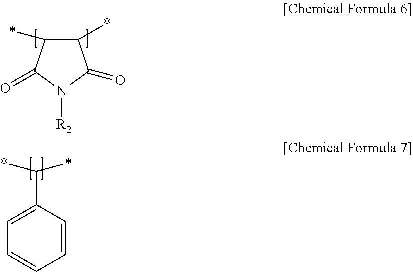
wherein, in Chemical Formula 6, R₂ is a substituted or unsubstituted aryl group having 6 to 30 carbon atoms or an alkyl group having 1 to 10 carbon atoms.

9. The positive-type photosensitive resin composition of claim 8, wherein the sum of the repeating units represented by Chemical Formula 6 or 7 is 30 mol % or less with respect to the total repeating units of the second polymer.

10. The positive-type photosensitive resin composition of claim 1, wherein each of the first polymer and the second polymer has a weight average molecular weight (Mw) of 1,000 to 50,000 g/mol.

11. The positive-type photosensitive resin composition of claim 1, wherein the first polymer contains a repeating unit represented by the following Chemical Formula 8 and a repeating unit represented by Chemical Formula 9: 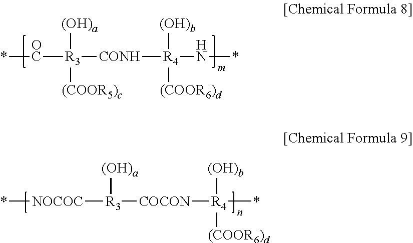
wherein, in Chemical Formulas 8 and 9, R₃ is a divalent to octavalent organic group having two or more carbon atoms, R₄ is a divalent to octavalent organic group having two or more carbon atoms, R₅ and R₆ are each independently a hydrogen atom or an organic group having 1 to 20 carbon atoms, a and b are each independently 0 to 4, c and d are each independently 0 to 2, and a+b is 1 or more, wherein when a, b, c, or d is 0, the corresponding substituent is a hydrogen atom, m and n represent molar ratios of the repeating unit represented by Chemical Formula 8 and the repeating unit represented by Chemical Formula 9, respectively, and m+n=100.

12. The positive-type photosensitive resin composition of claim 1, wherein the first polymer and the second polymer have a weight ratio of 50:50 to 95:5.

13. The positive-type photosensitive resin composition of claim 1, wherein the photosensitizer is contained in an amount of 5 to 50 parts by weight based on 100 parts by the total weight of the first polymer and the second polymer.

14. The positive-type photosensitive resin composition of claim 1, wherein the photosensitizer is a quinonediazide compound.

15. The positive-type photosensitive resin composition of claim 1, further comprising a phenolic hydroxyl group-containing crosslinkable compound.

16. The positive-type photosensitive resin composition of claim 15, wherein the phenolic hydroxyl group-containing crosslinkable compound includes one or more compounds selected from the group consisting of compounds represented by the following Chemical Formulas 10 to 27: 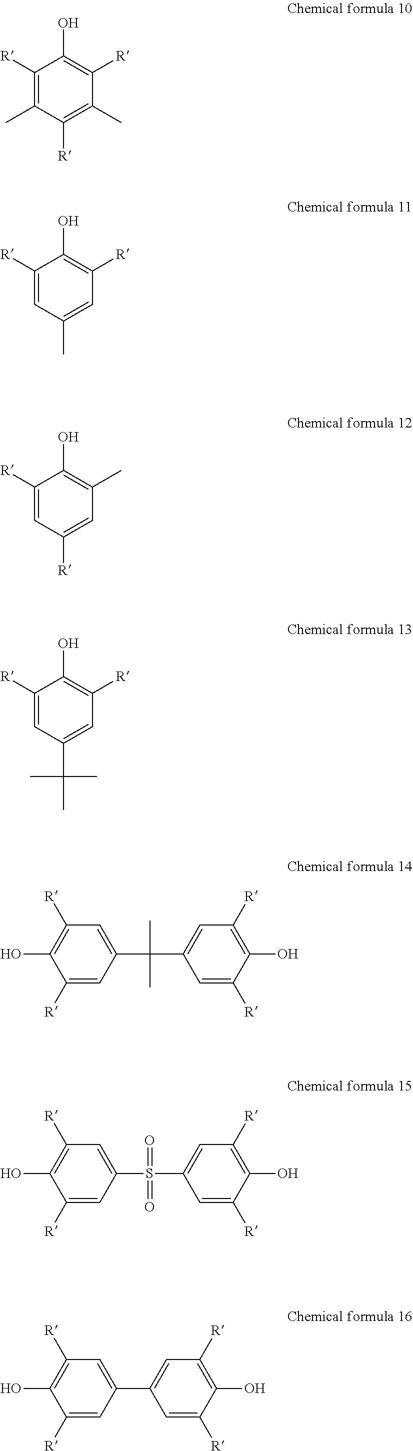 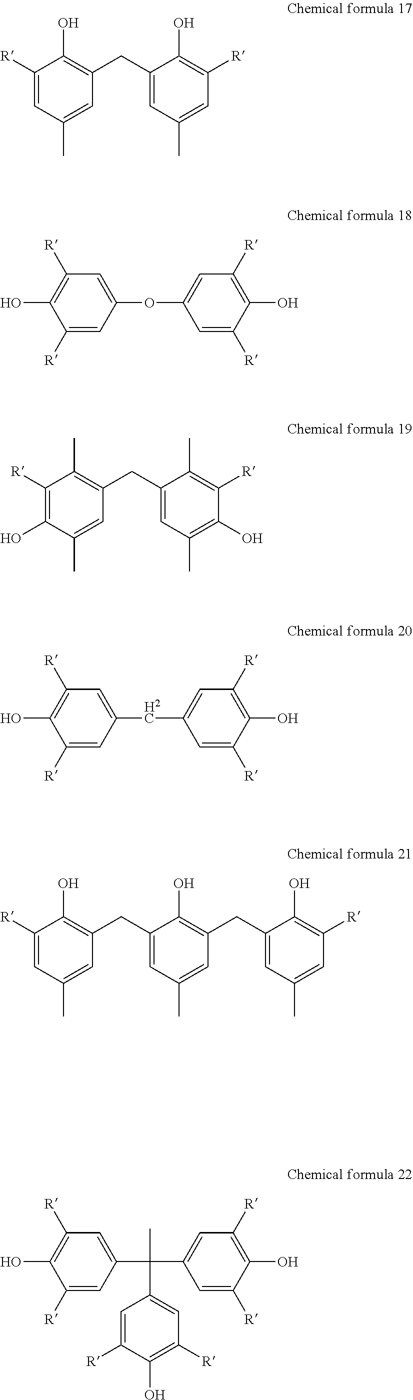 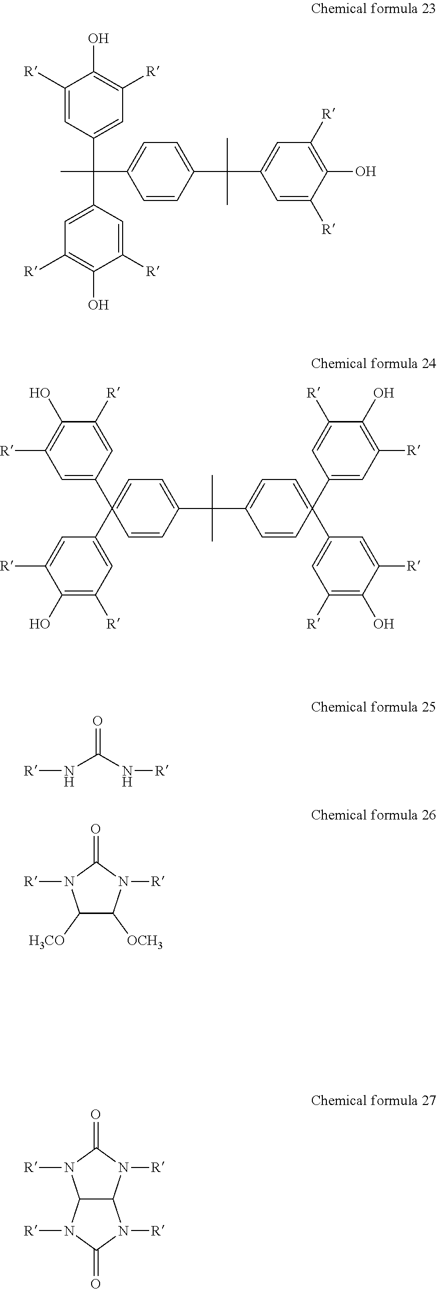
wherein, in Chemical Formulas 10 to 27, R′ are each independently one of a hydrogen atom, an alkyl group having 1 to 3 carbon atoms or one of substituents of Chemical Formula 28 below, at least one of R′ is a substituent of Chemical Formula 28 below, and in Chemical Formula 28 below, n is an integer of 1 to 6, and R₇ is an alkyl group having 1 to 3 carbon atoms:

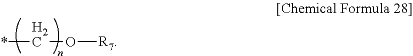

17. The positive-type photosensitive resin composition of claim 1, wherein the solvent includes one or more selected from the group consisting of gamma-butyrolactone (GBL), N-Methyl-2-pyrrolidone (NMP), propylene glycol methyl ether acetate (PGMEA), ethyl lactate (EL), methyl 3-methoxypropionate (MMP), propylene glycol monomethyl ether (PGME), diethylene glycol methyl ethyl ether (MEDG), diethylene glycol butyl methyl ether (MBDG), diethylene glycol dimethyl ether (DMDG), diethylene glycol diethyl ether (DEDG), and any mixtures thereof.

18. The positive-type photosensitive resin composition of claim 1, further comprising one or more additives selected from the group consisting of a thermal acid generator and a UV absorber.

19. An insulating film comprising a cured body of the positive-type photosensitive resin composition of claim 1.

20. A display device comprising the insulating film of claim 19.
